(19) United States
(12) Patent Application Publication
(10) Pub. No.: US 2024/0297174 A1
(43) Pub. Date: Sep. 5, 2024

(54) ARRAY SUBSTRATE, DISPLAY PANEL, AND DISPLAY DEVICE

(71) Applicant: WUHAN CHINA STAR OPTOELECTRONICS TECHNOLOGY CO., LTD., Wuhan, Hubei (CN)

(72) Inventors: Xuebin YUAN, Wuhan, Hubei (CN); Yanqing GUAN, Wuhan, Hubei (CN); Congxing YANG, Wuhan, Hubei (CN); Chao TIAN, Wuhan, Hubei (CN); Fuhsiung TANG, Wuhan, Hubei (CN)

(21) Appl. No.: 17/293,332

(22) PCT Filed: Mar. 31, 2021
(86) PCT No.: PCT/CN2021/084636

§ 371 Date: May 9, 2024

(30) Foreign Application Priority Data
Mar. 15, 2021 (CN) 202110273884.8

(51) Int. Cl. H01L 27/12

(52) U.S. Cl. CPC H01L 27/124

(57) ABSTRACT

The present application provides an array substrate, a display panel, and a display device. In the present application, a plurality of first-type data lines and a plurality of second-type data lines with data voltages of opposite polarities are provided, and a light-shielding layer of each of first sub-pixels is at least electrically connected to a light-shielding layer of one of second sub-pixels through a connecting line, which can effectively reduce a change in pixel brightness caused by capacitive coupling, and relieve a problem of image flicker.

### CROSS-REFERENCE TO RELATED APPLICATIONS

This application is a 371 U.S. National Stage of International Application No. PCT/CN2021/084636, filed on Mar. 31, 2021, which claims priority to Chinese Application No. 202110273884.8, filed on Mar. 15, 2021. The entire disclosures of the above applications are incorporated herein by reference.

### FIELD OF INVENTION

The present application relates to the field of display technology, and in particular to an array substrate, a display panel, and a display device.

### DESCRIPTION OF PRIOR ART

With the rapid development of science and technology in today's society, electronic products such as mobile phones, computers, and TVs are widely used in all aspects of life. Therefore, electronic displays such as liquid crystal displays (LCDs) and organic electroluminescence displays (OLEDs) are widely used.

In the prior art, a light-shielding layer is usually added between a channel region of an active layer and a base substrate of a thin film transistor (TFT) of a display panel, and the light-shielding layer can shield light directed to the active layer, thereby reducing an increase in leakage current caused by photo-generated carriers generated by light irradiating the active layer. However, a material of the light-shielding layer is usually metal or opaque non-metal, so the light-shielding layer and the active layer overlap each other to generate capacitance, and when the display panel is working, a source electrical signal changes, such that a capacitive coupling effect affects stored charges of pixels of the display panel, causing fluctuations in pixel voltage, so that brightness of the pixels changes, thus making the corresponding display panel flicker abnormally.

### SUMMARY OF INVENTION

### Technical Problem

The present application provides an array substrate, a display panel, and a display device, which can effectively reduce the change in pixel brightness caused by capacitive coupling, thereby relieving the problems such as flicker of the image.

### Solution of Problem

### Technical Solution

In order to solve the above problems, the technical solutions provided by the present application are as follows:

An array substrate, including:
a base substrate;
a plurality of data lines extending in a vertical direction, wherein the plurality of data lines include a plurality of first-type data lines and a plurality of second-type data lines arranged in parallel with the first-type data lines, and the first-type data lines and the second-type data lines are respectively configured with data voltages with opposite polarities;
a plurality of scan lines extending in a horizontal direction; and
a plurality of pixel units, wherein each of the pixel units includes a plurality of sub-pixels defined by intersecting the scan lines and the data lines, and the plurality of sub-pixels includes a plurality of first sub-pixels electrically connected to the first-type data lines and a plurality of second sub-pixels electrically connected to the second-type data lines,
wherein each of the sub-pixels is correspondingly provided with one of thin film transistors and one of light-shielding layers located between the thin film transistor and the base substrate, and one of the light-shielding layers corresponding to each of the first sub-pixels is at least electrically connected to one of the light-shielding layers corresponding to one of the second sub-pixels through a connecting line.

In the array substrate according to the present application, the first-type data lines and the second-type data lines are respectively configured to transmit data voltages of equal magnitude.

In the array substrate according to the present application, the first-type data lines and the second-type data lines are alternately arranged in the horizontal direction; and
the first sub-pixels and the second sub-pixels are alternately arranged in the horizontal direction to form pixel rows, and one of the light-shielding layers corresponding to each of the first sub-pixels is at least electrically connected to one of the light-shielding layers corresponding to adjacent one of the second sub-pixels through a connecting line.

In the array substrate according to the present application, a plurality of adjacent ones of the sub-pixels in each of the pixel rows form one of pixel groups, and the light-shielding layers corresponding to the sub-pixels in a same one of the pixel groups are electrically connected through the connecting line.

In the array substrate according to the present application, each of the pixel rows includes one or more of the pixel groups.

In the array substrate according to the present application, each of the pixel rows includes a plurality of the pixel groups, and each of the pixel groups includes a same number of the sub-pixels.

In the array substrate according to the present application, each of the pixel rows includes a plurality of first pixel groups arranged in succession, and each of the first pixel groups includes N number of adjacent ones of the sub-pixels, where N is a positive integer greater than or equal to 2.

In the array substrate according to the present application, the first pixel groups located in the adjacent ones of the pixel rows are dislocated from each other.

In the array substrate according to the present application, N is an even number, and a dislocation distance is a distance between 1 to (N−1) number of the sub-pixels.

In the array substrate according to the present application, the dislocation distance between the first pixel groups located in the adjacent ones of the pixel rows is a spacing of N/2 adjacent ones of the sub-pixels.

In the array substrate according to the present application, N=6, and each of the first pixel groups includes at least one red sub-pixel, one blue sub-pixel, and one green sub-pixel.

In the array substrate according to the present application, at least part of the pixel rows further includes a second pixel group located at an edge of the pixel rows and adjacent to one of the first pixel groups, and each of the second pixel groups includes M number of adjacent ones of the sub-pixels, where M is a positive integer greater than or equal to 1, M≠N, and M<2N.

In the array substrate according to the present application, in each of the sub-pixels, the one of the thin film transistors includes an active layer, a gate, a source, and a drain that are stacked;
the active layer includes a channel region, a lightly doped region, and a heavily doped region; and
an orthographic projection of one of the light-shielding layers on the active layer covers the channel region, the lightly doped region, and the heavily doped region.

In the array substrate according to the present application, a distance between a boundary of an orthographic projection of one of the light-shielding layers on the base substrate and a boundary of an orthographic projection of the channel region adjacent to the one of the light-shielding layers on the base substrate is a, and a ≥2 microns.

In the array substrate according to the present application, an orthographic projection of the connecting line on the base substrate and an orthographic projection of the gate on the base substrate do not overlap.

In the array substrate according to the present application, a width of the connecting line ranges from 1 micron to 15 microns.

In the array substrate according to the present application, a thickness of the light-shielding layer and a thickness of the connecting line both range from 300 Å to 1500 Å.

In the array substrate according to the present application, a thickness of the connecting line and a thickness of the light-shielding layer are same.

The present application also provides a display panel, wherein the display panel includes an array substrate and a second substrate disposed above thin film transistors of the array substrate, and a black matrix is disposed on a side of the second substrate close to the array substrate, wherein
the array substrate includes:
a base substrate;
a plurality of data lines extending in a vertical direction, wherein the plurality of data lines include a plurality of first-type data lines and a plurality of second-type data lines arranged in parallel with the first-type data lines, and the first-type data lines and the second-type data lines are respectively configured with data voltages with opposite polarities;
a plurality of scan lines extending in a horizontal direction; and
a plurality of pixel units, wherein each of the pixel units includes a plurality of sub-pixels defined by intersecting the scan lines and the data lines, and the plurality of sub-pixels includes a plurality of first sub-pixels electrically connected to the first-type data lines and a plurality of second sub-pixels electrically connected to the second-type data lines,
wherein each of the sub-pixels is correspondingly provided with one of thin film transistors and one of light-shielding layers located between the thin film transistor and the base substrate, and one of the light-shielding layers corresponding to each of the first sub-pixels is at least electrically connected to one of the light-shielding layers corresponding to one of the second sub-pixels through a connecting line; and
wherein an orthographic projection of the black matrix on the array substrate covers the connecting line.

The present application still provides a display device including any one of the above-mentioned display panels.

### Beneficial Effect of Invention

### Beneficial Effect

In the present application, a light-shielding layer is added between the active layer of the array substrate and the base substrate to reduce the light emitted to the active layer in the corresponding display panel, thereby reducing the photo-generated current generated by light irradiating the active layer. Meanwhile, by arranging a plurality of first-type data lines with opposite polarity data voltages and a plurality of second-type data lines arranged in parallel with the first-type data lines, wherein the first-type data lines are electrically connected to a plurality of first sub-pixels, the second-type data lines are electrically connected to a plurality of second sub-pixels, and one of the light-shielding layers corresponding to each of the first sub-pixels is at least electrically connected to one of the light-shielding layers corresponding to one of the second sub-pixels through a connecting line, so that when the corresponding display panel is working, the capacitive coupling directions of the first sub-pixel and the second sub-pixel are opposite, which reduces the voltage of the sub-pixels, thereby effectively reducing the change in the pixel brightness caused by the capacitive coupling, thus relieving the problems such as image flicker.

### BRIEF DESCRIPTION OF DRAWINGS

### Description of Drawings

The following detailed description of specific implementations of the present application in conjunction with the accompanying drawings will make the technical solutions and other beneficial effects of the present application obvious.

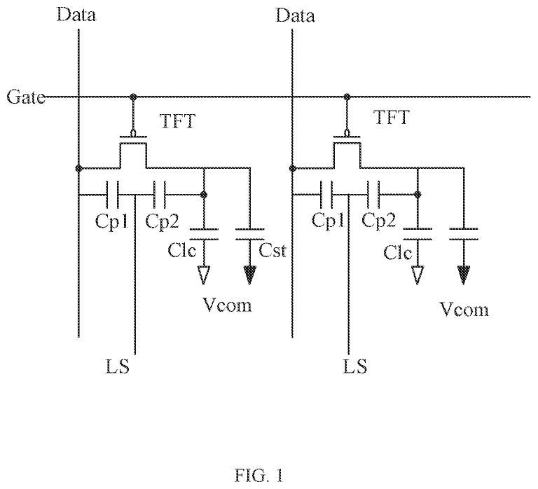

FIG. 1 is a schematic diagram of an equivalent circuit of sub-pixels of a conventional array substrate.

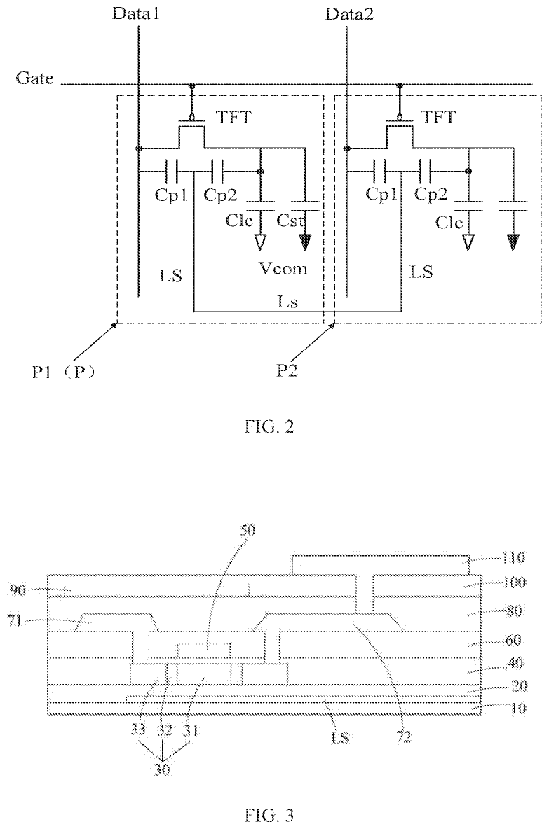

FIG. 2 is a schematic diagram of an equivalent circuit of sub-pixels of an array substrate provided by the present application.

FIG. 3 is a schematic structural diagram of an array substrate provided by an embodiment of the present application.

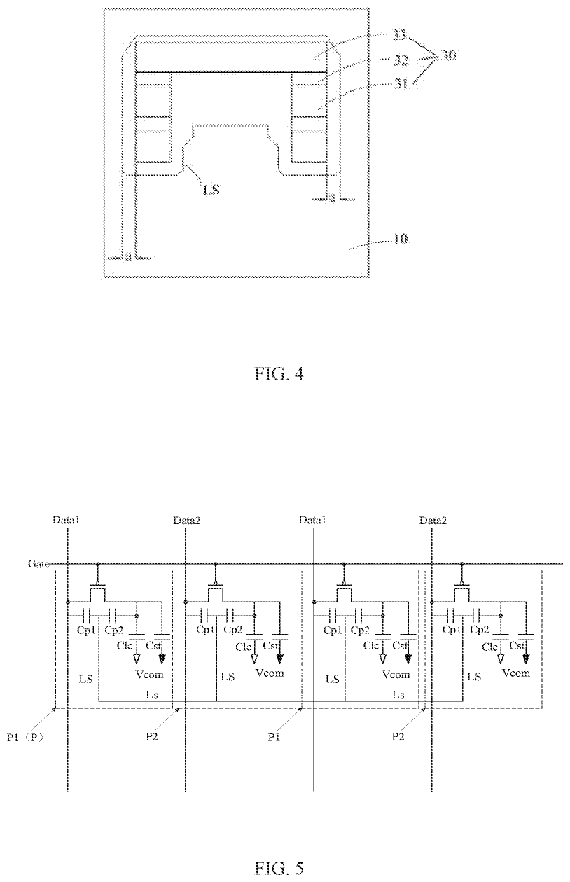

FIG. 4 is a top view of an active layer and a light-shielding layer of the array substrate provided by an embodiment of the present application.

FIG. 5 is a schematic diagram of an equivalent circuit of sub-pixels of the array substrate provided by an embodiment of the present application.

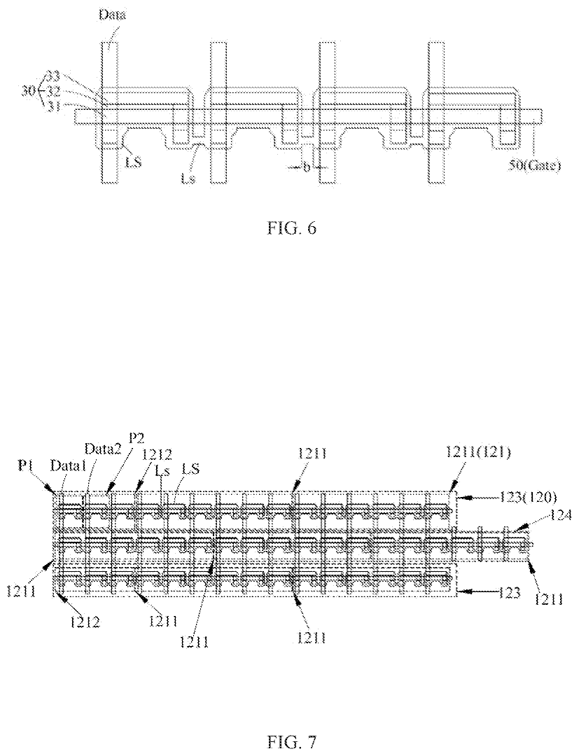

FIG. 6 is a top view of the array substrate provided by an embodiment of the present application.

FIG. 7 is a schematic diagram of a first arrangement of the sub-pixels at an edge of the array substrate provided by an embodiment of the present application.

FIG. 8 is a schematic diagram of a second arrangement of the sub-pixels at the edge of the array substrate provided by an embodiment of the present application.

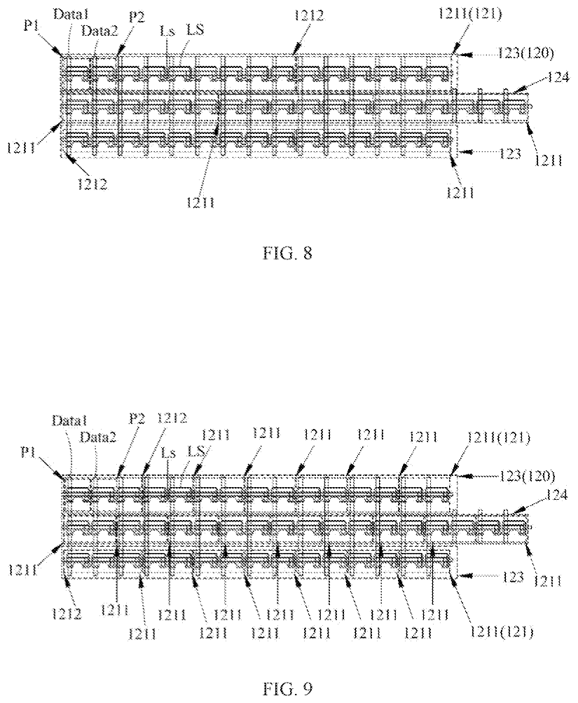

FIG. 9 is a schematic diagram of a third arrangement of the sub-pixels at the edge of the array substrate provided by an embodiment of the present application.

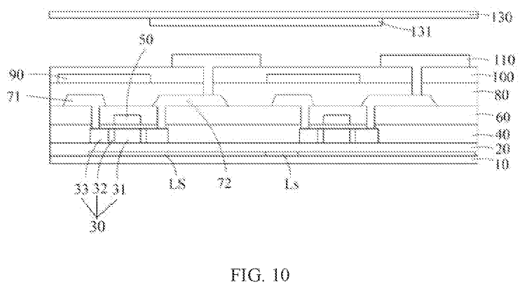

FIG. 10 is a schematic structural diagram of a display panel provided by an embodiment of the present application.

### EMBODIMENTS OF INVENTION

### Detailed Description of Preferred Embodiments

The present application provides an array substrate, a display panel, and a display device. In order to make the objects, technical solutions, and effects of the present application more definite and clearer, the present application will be further described in detail below with reference to the accompanying drawings and embodiments. It should be understood that the specific embodiments described here are only used to explain the present application, and are not used to limit the present application.

Referring to FIG. 1, a schematic diagram of an equivalent circuit of the sub-pixels of a conventional array substrate is shown.

In the prior art, an array substrate includes a base substrate, a plurality of data lines Data extending in a vertical direction, a plurality of scan lines Gate extending in a horizontal direction, and a plurality of pixel units, wherein each of the pixel units includes a plurality of sub-pixels defined by intersecting the scan lines Gate and the data lines Data, each of the sub-pixels includes a thin film transistor TFT, a storage capacitor Cst, and a liquid crystal capacitor Clc, and a gate of the thin film transistor TFT is connected to the corresponding scan line Gate, a source of the thin film transistor TFT is connected to the corresponding data line Data, and a drain of the thin film transistor TFT is connected to a first electrode plate of the liquid crystal capacitor Clc and a first electrode plate of the storage capacitor Cst. In order to reduce the light emitted to the active layer of the thin film transistor TFT in the corresponding display panel, thereby reducing the leakage current caused by the photo-generated carriers generated by the light irradiating the active layer, a light-shielding layer LS is usually added between the thin film transistor TFT and the base substrate.

However, since the material of the light-shielding layer LS is metal or opaque non-metal, a first capacitor CP1 is formed between the light-shielding layer LS and the source, and a second capacitor CP2 is formed between the light-shielding layer LS and the drain. When the corresponding display panel is working, the source electrical signal changes, such that the capacitive coupling effect affects the stored charges of the pixels of the display panel, causing fluctuations in the pixel voltage, so that the brightness of the pixels changes, thus making the corresponding display panel flicker abnormally. In view of this, the present application provides an array substrate, a display panel, and a display device to solve the above-mentioned problems.

Referring to FIG. 2, a schematic diagram of an equivalent circuit of the sub-pixels of the array substrate provided by the present application is shown.

The present application provides an array substrate, the array substrate includes a base substrate (not shown); a plurality of data lines Data extending in a vertical direction, the plurality of data lines Data includes a plurality of first-type data lines Data1 and a plurality of second-type data lines Data2 arranged in parallel with the first-type data line Data1, the first-type data line Data1 and the second-type data line Data2 are respectively configured with data voltages with opposite polarities; and a plurality of scan lines Gate extending in a horizontal direction.

The array substrate further includes a plurality of pixel units (not shown), and each of the pixel units includes a plurality of sub-pixels (not shown) defined by intersecting the scan lines Gate and the data lines Data. Each of the sub-pixels includes a plurality of first sub-pixels P1 electrically connected to the first-type data lines Data1 and a plurality of second sub-pixels P2 electrically connected to the second-type data lines Data2.

Each of the sub-pixels is correspondingly provided with a thin film transistor TFT and a light-shielding layer LS located between the thin-film transistor TFT and the base substrate, and the light-shielding layer corresponding to each of the first sub-pixels P1 is electrically connected to the light-shielding layer LS corresponding to at least one of the second sub-pixels P2 through a connecting line Ls.

It should be noted that the number of the sub-pixels, the number of the first sub-pixels P1, and the number of the second sub-pixels P2 are not specifically limited in the present application.

In the present application, the first sub-pixel P1 and the second sub-pixel P2 further include a storage capacitor Cst and a liquid crystal capacitor Clc, the gate of the thin film transistor TFT is connected to the corresponding scan line Gate, the source of the thin film transistor TFT is connected to the corresponding data line Data, the drain of the thin film transistor TFT is connected to the first electrode plate of the liquid crystal capacitor Clc and the first electrode plate of the storage capacitor Cst, a first capacitor CP1 is formed between the light-shielding layer LS and the source of the thin film transistor TFT, and a second capacitor CP2 is formed between the light-shielding layer LS and the drain of the thin film transistor TFT.

The array substrate provided in the present application includes a plurality of data lines extending in a vertical direction, wherein the plurality of data lines include a plurality of first-type data lines Data1 and a plurality of second-type data lines Data2 arranged in parallel with the first-type data lines Data1, the first-type data line Data1 and the second-type data line Data2 are respectively configured with data voltages with opposite polarities; and a plurality of pixel units, wherein each of the pixel units includes a plurality of sub-pixels defined by intersecting the scan lines and the data lines, and the plurality of sub-pixels includes a plurality of first sub-pixels P1 electrically connected to the first-type data lines Data1 and a plurality of second sub-pixels P2 electrically connected to the second-type data lines Data2. The light-shielding layer LS corresponding to each of the first sub-pixels P1 is electrically connected to the light-shielding layer LS corresponding to at least one of the second sub-pixels P2 through a connection line Ls, so that when the corresponding display panel is working, the capacitive coupling directions of the first sub-pixel P1 and the second sub-pixel P2 are opposite, which reduces the voltage of the sub-pixels, thereby effectively reducing changes in pixel brightness caused by capacitive coupling, and relieving problems such as image flicker.

It should be noted that in the present application, each of the first sub-pixels P1 and the second sub-pixels P2 includes but are not limited to a red sub-pixel (R), a green sub-pixel (G), or a blue sub-pixel (B).

It is appreciated that in the present application, the types of the first sub-pixel P1 and the second sub-pixel P2 are not further limited, that is, the types of first sub-pixel P1 and the second sub-pixel P2 can be the same or different.

The technical solution of the present application will now be described in conjunction with specific embodiments.

### Embodiment 1

Referring to FIG. 3, a schematic diagram of the structure of the array substrate provided by the embodiment of the present application is shown.

This embodiment provides an array substrate. The array substrate includes a base substrate 10 and a plurality of pixel units (not shown) on the base substrate 10, wherein each of the pixel units includes a plurality of sub-pixels (not shown), and each of the sub-pixels is correspondingly provided with a thin film transistor TFT located on the base substrate 10 and a light-shielding layer LS located between the thin film transistor TFT and the base substrate 10.

In this embodiment, the material of the base substrate 10 includes but is not limited to polyethylene terephthalate, polyimide, triacetate film, or other flexible materials. Further, the base substrate 10 is polyimide (P1) substrate, mainly made of polyimide (P1). P1 material can effectively improve the light transmittance of the substrate.

In this embodiment, the thin film transistor TFT includes an active layer 30, a gate insulating layer 40, a gate 50, an interlayer insulating layer 60, a source 71, a drain 72, a planarization layer 80, a common electrode layer 90, a passivation layer 100, and a pixel electrode 110 which are sequentially stacked on the light-shielding layer LS, wherein the source 71 and the drain 72 are arranged in the same layer and spaced apart from each other, and the pixel electrode 110 passing through a via hole (not shown) is electrically connected to the drain 72.

In this embodiment, the material of the active layer 30 includes, but is not limited to, indium gallium zinc oxide. The gate insulating layer 40 and the interlayer insulating layer 60 have strong water and oxygen barrier capabilities and insulating capabilities, and are made of materials including, but not limited to silicon oxide, silicon nitride, silicon oxynitride, and the like or a stack thereof. The materials of the gate 50, the source 71, and the drain 72 include, but are not limited to metals such as molybdenum, silver, aluminum, and the like or a stack thereof. The material of the passivation layer 100 includes but is not limited to silicon oxide, silicon nitride, silicon oxynitride, and the like or a stack thereof. The materials of the common electrode layer 90 and the pixel electrode 110 include, but are not limited to indium oxide tin.

In this embodiment, the array substrate further includes a buffer layer 20 located between the active layer 30 and the light-shielding layer LS, and the buffer layer 20 may be made of silicon oxide or silicon nitride.

It should be noted that, in this embodiment, the array substrate includes the buffer layer 20, the active layer 30, the gate insulating layer 40, the gate 50, the interlayer insulating layer 60, the source 71, the drain 72, the planarization layer 80, the common electrode layer 90, the passivation layer 100, and the pixel electrode 110 which are sequentially stacked and disposed on the light-shielding layer LS for illustration only. Meanwhile, the pixel electrode 110 and the drain 72 being electrically connected is only for illustration, and the pixel electrode 110 may also be connected to the source 71, which is not specifically limited in this embodiment.

Referring to FIG. 4, a top view of the active layer and the light-shielding layer of the array substrate provided by the embodiment of the present application is shown.

In this embodiment, the active layer 30 includes a channel region 31, a lightly doped region 32, and a heavily doped region 33. The channel region 31 is located between the two lightly doped regions 32, and the channel region 31 and the lightly doped region 32 are located between the two heavily doped regions 33. The projection of the light-shielding layer LS on the active layer 30 covers the channel region 31, the lightly doped region 32, and the heavily doped region 33.

Specifically, the projection of the light-shielding layer LS on the active layer 30 at least overlaps the boundary of a side of the heavily doped region 33 away from the lightly-doped region 32. The thickness of the light-shielding layer LS ranges from 300 Å to 1500 Å.

Specifically, a distance between a boundary of an orthographic projection of one of the light-shielding layers LS on the base substrate 10 and a boundary of an orthographic projection of the channel region 31 adjacent to the one of the light-shielding layers LS on the base substrate 10 is a, and a ≥2 microns. By limiting the range of a, the incidence of light from a side of the base substrate 10 away from the active layer 30 into the channel region 31 and the lightly doped region 32 of the active layer 30 is reduced, ensuring the light-shielding properties of the channel region 31 and the lightly doped region 32. Meanwhile, in order to obtain the light-shielding layer LS with better light-shielding performance and high mass production feasibility, preferably, the thickness of the light-shielding layer LS is in the range of 600 Å to 1000 Å.

In this embodiment, the projection of the light-shielding layer LS on the active layer 30 at least overlaps with the boundary of a side of the heavily doped region 33 away from the lightly doped region 32, so as to planarize a side the active layer 30 close to the base substrate 10, thereby preventing the active layer 30 from undesirable phenomena such as disconnecting.

In this embodiment, the light-shielding layer LS is added between the active layer 30 of the array substrate and the base substrate 10, and the orthographic projection of the active layer 30 on the base substrate 10 is located in the orthographic projection of the light-shielding layer LS on the base substrate 10, thereby reducing the light emitted from the array substrate to the active layer 30, thus reducing the leakage current caused by the photo-generated carriers generated by the light irradiating the active layer 30.

Referring to FIG. 5, a schematic diagram of an equivalent circuit of the sub-pixels of the array substrate provided by an embodiment of the present application is shown.

In this embodiment, the array substrate further includes a plurality of data lines Data extending in a vertical direction, and the plurality of data lines Data includes a plurality of first-type data lines Data1 and a plurality of second-type data lines Data2 arranged in parallel with the first-type data lines Data1, the first-type data line Data1 and the second-type data line Data2 are respectively configured with data voltages with opposite polarities; a plurality of scan lines Gate extending in the horizontal direction; wherein each of the pixel units (not shown) includes a plurality of sub-pixels P defined by intersecting the scan lines Gate and the data lines Data, and the plurality of sub-pixels P include a plurality of first sub-pixels P1 electrically connected to the first-type data lines Data1 and a plurality of second sub-pixels P2 electrically connected to the second-type data line Data2, and the light-shielding layer LS corresponding to each of the first sub-pixels P1 is electrically connected to the light-shielding layer LS corresponding to at least one second sub-pixel P2 adjacent to the first sub-pixel P1 through the connecting line Ls.

In this embodiment, a plurality of first-type data lines Data1 and a plurality of second-type data lines Data2 arranged in parallel with the first-type data lines Data1 are provided with opposite polarity data voltages, the first-type data lines Data1 are electrically connected to the plurality of first sub-pixels P1, the second-type data lines Data2 are electrically connected to the plurality of second sub-pixels P2, and the light-shielding layer LS corresponding to each of the first sub-pixels P1 is at least electrically connected to the light-shielding layer LS corresponding to the second sub-pixel P2 adjacent to the first sub-pixel P1 through the connecting line Ls, so that when the corresponding display panel is working, the capacitive coupling directions of the first sub-pixel P1 and the second sub-pixel P2 are opposite, which reduces the voltage of the sub-pixels, thereby effectively reducing changes in pixel brightness caused by capacitive coupling, and relieving problems such as image flicker.

Further, the first-type data line Data1 and the second-type data line Data2 are respectively configured to transmit data voltages of equal magnitude.

Specifically, in an embodiment, the first-type data lines Data1 and the second-type data lines Data2 are alternately arranged in a horizontal direction; the first sub-pixels P1 and the second sub-pixels P2 are arranged along the horizontal direction. The light-shielding layer LS corresponding to each of the first sub-pixels P1 and the light-shielding layer LS corresponding to at least one adjacent second sub-pixel P2 are arranged alternately in sequence in the horizontal direction through the connecting line Ls, so that when the corresponding display panel is working, the capacitive coupling directions of the first sub-pixel P1 and the second sub-pixel P2 are opposite, and the data voltage change in the first sub-pixel P1 and the data voltage change in the second sub-pixel P1 are both zero, thereby effectively reducing changes in pixel brightness caused by capacitive coupling, and relieving problems such as image flicker.

In this embodiment, the first sub-pixel P1 and the second sub-pixel P2 further include a storage capacitor Cst and a liquid crystal capacitor Clc, the gate 50 of the thin film transistor TFT is connected to the corresponding scan line Gate, and the source 71 of the thin film transistor TFT is connected to the corresponding data line Data, the drain 72 of the thin film transistor TFT is connected to the first electrode plate of the liquid crystal capacitor Clc and the first electrode plate of the storage capacitor Cst, a first capacitor CP1 is formed between the light-shielding layer LS and the source 71 of the thin film transistor TFT, a second capacitor CP2 is formed between the light-shielding layer LS and the drain 72 of the thin film transistor TFT, and the light-shielding layer LS corresponding to the first sub-pixel P1 is electrically connected to the light-shielding layer LS corresponding to the adjacent second sub-pixel P2 through the connecting line Ls.

Referring to FIG. 6, a top view of the array substrate provided by the embodiment of the present application is shown.

In this embodiment, the connecting line Ls and the light-shielding layer LS are arranged in the same layer, and the material of the connecting line Ls is the same as that of the light-shielding layer LS. When the material of the connecting line Ls is a metal material in order to prevent the connecting line Ls and the scan line Gate from overlapping to generate parasitic capacitance, the orthographic projection of the connecting line Ls on the base substrate 10 and the orthographic projection of the scan line Gate on the base substrate 10 do not overlap.

It is appreciated that, in this embodiment, the connecting line Ls and the light-shielding layer LS are made of the same material, so the connecting line Ls and the light-shielding layer LS may be an integrally formed structure, thereby reducing the number of the manufacturing processes of the array substrate and improving the production efficiency. Of course, the connecting line Ls and the light-shielding layer LS can also be formed separately, which is not further limited in this embodiment.

In this embodiment, the orthographic projection of the connecting line Ls on the base substrate 10 and the orthographic projection of the scan line Gate on the base substrate 10 do not overlap, so as to prevent the parasitic capacitance generated by overlapping the scan lines Gate with the connecting line Ls when the material of the connecting line Ls is a metal, which may impact the display effect of the corresponding display panel.

Specifically, the width b of the connecting line Ls ranges from 1 μm to 15 μm, and the thickness of the connecting line Ls ranges from 300 Å to 1500 Å. Further, the thickness of the connecting line Ls and the thickness of the light-shielding layer Ls are the same.

Referring to FIG. 7, a schematic diagram of a first arrangement of the sub-pixels on the array substrate provided by an embodiment of the present application is shown.

In this embodiment, the first-type data lines Data1 and the second-type data lines Data2 are alternately arranged in the horizontal direction. The first sub-pixels P1 and the second sub-pixels P2 are alternately arranged in the horizontal direction to form first pixel rows 120. The light-shielding layer LS corresponding to each of the first sub-pixels P1 is electrically connected to the light-shielding layer LS corresponding to at least one adjacent second sub-pixel P2 through the connecting line Ls.

In this embodiment, a plurality of adjacent ones of the sub-pixels P in each of the pixel rows 120 form one of pixel groups 121, and the light-shielding layers LS corresponding to the sub-pixels P in a same one of the pixel groups 121 are electrically connected through the connecting line Ls.

In this embodiment, each of the pixel rows 120 includes one or more of the pixel groups 121.

Specifically, each of the pixel rows 120 includes a plurality of the pixel groups 121, and each of the pixel groups 121 includes the same number of the sub-pixels P; wherein each of the pixel rows 120 includes a plurality of first pixel groups 1211 arranged in succession, and each of the first pixel groups 1211 includes N number of adjacent ones of the sub-pixels P, where N is a positive integer greater than or equal to 2.

In this embodiment, the first pixel groups 1211 located in the adjacent ones of the pixel rows 120 are dislocated from each other.

When N is an even number, a dislocation distance is a distance between 1 to (N−1) number of the sub-pixels P, and the dislocation distance between the first pixel groups 1211 located in the adjacent ones of the pixel rows 120 is preferably a spacing of N/2 adjacent ones of the sub-pixels P. In this case, the capacitive coupling directions of the first sub-pixel P1 and the second sub-pixel P2 are opposite, according to the sub-pixel voltage change [2V*CP1*N+(−2V*CP1)*N]/2N, it can be seen that the data voltage change in the first sub-pixel P1 and the data voltage change in the second sub-pixel P2 are both zero.

When N is an odd number, the dislocation distance is 1 to (N−1) number of a spacing of the sub-pixels P, and the dislocation distance between the first pixel groups 1211 located in the adjacent ones of the pixel rows 120 is preferably a spacing of (N+1)/2 adjacent ones of the sub-pixels P. In this case, the capacitive coupling directions of the first sub-pixel P1 and the second sub-pixel P2 are opposite. According to the sub-pixel voltage change: [2V*CP1*(N+1)+(−2V*CP1)*N]/2N=(2V*CP1)/(2N+1), it can be seen that when N is an odd number, the voltage of the sub-pixel decreases, and that when N is sufficiently large, the data voltage change in the first sub-pixel P1 and the data voltage change in the second sub-pixel P2 are approximately zero.

In this embodiment, the light-shielding layer LS corresponding to each of the first sub-pixels P1 is electrically connected to the light-shielding layer LS corresponding to one of the second sub-pixels P2 through a connecting line Ls, so that when the corresponding display panel is working, the capacitive coupling directions of the first sub-pixel and the second sub-pixel are opposite, which reduces the voltage of the sub-pixels, thereby effectively reducing the change in the pixel brightness caused by the capacitive coupling, thus relieving the problems such as image flicker.

Specifically, in this embodiment, the pixel rows 120 includes a first pixel row 123 and a second pixel row 124 that are alternately arranged in the vertical direction, wherein the first pixel row 123 includes a plurality of first pixel groups 1211 arranged in succession and a second pixel group 1212 located at the edge of the pixel row 120 and adjacent to one of the first pixel groups 1211, the second pixel row 124 includes a plurality of first pixel groups 1211 arranged in succession, the first pixel group 1211 includes 6 of adjacent ones of the sub-pixels P, and the second pixel group 1212 includes 3 of adjacent ones of the sub-pixels P. The dislocation distance between the first pixel groups 1211 located in the adjacent ones of the pixel rows 120 is a spacing of 3 of adjacent ones of the sub-pixels P, and the first pixel group 1211 includes at least one red sub-pixel, one blue sub-pixel, and one green sub-pixel.

In this embodiment, at least part of the pixel rows 120 further includes a second pixel group 1212 located at an edge of the pixel rows 120 and adjacent to one of the first pixel groups 1211, and each of the second pixel groups 1212 includes M number of adjacent ones of the sub-pixels P, where M is a positive integer greater than or equal to 1, M≠N, and M<2N.

It can be appreciated that in FIG. 7, the dislocation arrangement of the first pixel rows 123 and the second pixel rows 124 is only used as an example for illustration. The order of alternately arranging the pixel rows 123 and the second pixel rows 124 is not specifically limited. Meanwhile, the number of the first pixel rows 123 and the number of the second pixel rows 124 are not specifically limited in this embodiment.

Referring to FIG. 8, a schematic diagram of the second arrangement of the sub-pixels at the edge of the array substrate provided by an embodiment of the present application is shown.

In this embodiment, the arrangement of the sub-pixels is similar or substantially the same as the first arrangement of the sub-pixels provided in the foregoing embodiment. Details can be referred to the description of the arrangement of the sub-pixels in the foregoing embodiment, which will not be repeated herein for brevity, and the difference therebetween is only in that as follows:

In this embodiment, N=6, and M=9, that is, the first pixel group 1211 includes 6 of adjacent ones of the sub-pixels P, and the second pixel group 1212 includes 9 adjacent ones of the sub-pixels P, wherein the dislocation distance between the first pixel groups 1211 located in the adjacent pixel rows 120 is a spacing of three adjacent ones of the sub-pixels P.

Referring to FIG. 9, a schematic diagram of a third arrangement of the sub-pixels at the edge of the array substrate provided by an embodiment of the present application is shown.

In this embodiment, the arrangement of the sub-pixels is similar or substantially the same as the first arrangement of the sub-pixels provided in the foregoing embodiment. Details can be referred to the description of the arrangement of the sub-pixels in the foregoing embodiment, which will not be repeated herein for brevity, and the difference therebetween is only in that as follows:

In this embodiment, N=2, and M=3, that is, the first pixel group 1211 includes two of adjacent ones of the sub-pixels P, and the second pixel group 1212 includes three of adjacent ones of the sub-pixels P, wherein the dislocation distance between the first pixel groups 1211 located in the adjacent pixel rows 120 is a spacing of adjacent ones of the sub-pixels P.

In this embodiment, by dislocating the first pixel groups 1211 of adjacent ones of the pixel rows 120, the uniformity of the arrangement at the intervals between the adjacent pixel groups can be improved. Otherwise, when the first pixel groups 1211 of the adjacent pixel rows 120 are arranged correspondingly, the absence of the connecting lines Ls between adjacent first pixel groups 1211 will result in poor uniformity of the arrangement at the intervals between the adjacent ones of the first pixel groups 1211, causing a poor display effect in this area.

It should be noted that the above-mentioned FIGS. 7, 8, and 9 are only exemplary descriptions of the technical solutions of the present application, that is, in this embodiment, the first pixel group 1211 includes 6 sub-pixels P, and the second pixel group 1212 includes three adjacent sub-pixels P; the first pixel group 1211 includes six sub-pixels P, and the second pixel group 1212 includes nine adjacent sub-pixels P; the first pixel group 1211 includes two adjacent sub-pixels P, and the second pixel group 1212 includes three adjacent sub-pixels P, which are all for illustration purposes only. The number of sub-pixels P may be selected based on the actual product needs.

It can be understood that the dislocation distance between the first pixel groups 1211 located in the adjacent ones of the pixel rows 120 being a spacing of N/2 adjacent ones of the sub-pixels is only for illustration. Embodiments of the present application are not specifically limited to the dislocation distance between the first pixel groups 1211 of the adjacent pixel rows 120.

### Embodiment 2

Referring to FIG. 10, a schematic structural diagram of a display panel provided by an embodiment of the present application is shown.

This embodiment also provides a display panel, including the array substrate in the first embodiment above, and a second substrate 130 disposed above the thin film transistor TFT of the array substrate, wherein a black matrix 131 is provided on a side of the second substrate 130 close to the array substrate.

A projection of the black matrix 131 on the array substrate covers the connecting line Ls.

In this embodiment, the array substrate has been described in detail in the above embodiments, and the description will not be repeated herein for brevity.

In this embodiment, the projection of the black matrix 131 on the array substrate covers the connecting line Ls, that is, the connecting line Ls is located directly under the black matrix 131, thereby preventing a loss in the opening rate of the display panel, thus achieving the purpose of improving the display effect of the display panel.

### Embodiment 3

This embodiment also provides a display device, which includes the display panel in the second embodiment or the array substrate in the first embodiment.

The array substrate has been described in detail in the above-mentioned embodiments, and the description will not be repeated herein for brevity.

In specific applications, the display device may be the display screen of a smart phone, tablet computer, notebook computer, smart bracelet, smart watch, smart glasses, smart helmet, desktop computer, smart TV, or digital camera, which can be even applied to electronic devices with flexible display screens.

In summary, the present application provides an array substrate, a display panel, and a display device. The array substrate includes a base substrate, a plurality of data lines, a plurality of scan lines, and a plurality of pixel units; wherein the plurality of data lines includes a plurality of first-type data lines and a plurality of second-type data lines arranged in parallel with the first-type data lines; the first-type data lines and the second-type data lines are respectively configured to transmit data voltages of equal magnitude and opposite polarity; each of the pixel units includes a plurality of sub-pixels defined by intersecting the scan lines and the data lines, the plurality of sub-pixels include a plurality of first sub-pixels electrically connected to the first-type data lines and a plurality of second sub-pixels electrically connected to the second-type data lines; and the light-shielding layer corresponding to each of the first sub-pixels is electrically connected to the light-shielding layer corresponding to at least one of the second sub-pixels through a connecting line. The display panel and display device provided by the present application can effectively relieve the problem of image flicker caused by capacitive coupling.

It can be understood that for those of ordinary skill in the art, equivalent substitutions or changes can be made according to the technical solution and inventive concept of the present application, and all these changes or substitutions should fall within the protection scope of the appended claims of the present application.

1. An array substrate, comprising:
a base substrate;
a plurality of data lines extending in a vertical direction, wherein the plurality of data lines comprise a plurality of first-type data lines and a plurality of second-type data lines arranged in parallel with the first-type data lines, and the first-type data lines and the second-type data lines are respectively configured with data voltages with opposite polarities;
a plurality of scan lines extending in a horizontal direction; and
a plurality of pixel units, wherein each of the pixel units comprises a plurality of sub-pixels defined by intersecting the scan lines and the data lines, and the plurality of sub-pixels comprise a plurality of first sub-pixels electrically connected to the first-type data lines and a plurality of second sub-pixels electrically connected to the second-type data lines,
wherein each of the sub-pixels is correspondingly provided with one of thin film transistors and one of light-shielding layers located between the thin film transistor and the base substrate, and one of the light-shielding layers corresponding to each of the first sub-pixels is at least electrically connected to one of the light-shielding layers corresponding to one of the second sub-pixels through a connecting line.

2. The array substrate according to claim 1, wherein the first-type data lines and the second-type data lines are respectively configured to transmit data voltages of equal magnitude.

3. The array substrate according to claim 1, wherein the first-type data lines and the second-type data lines are alternately arranged in the horizontal direction; and
the first sub-pixels and the second sub-pixels are alternately arranged in the horizontal direction to form pixel rows, and one of the light-shielding layers corresponding to each of the first sub-pixels is at least electrically connected to one of the light-shielding layers corresponding to adjacent one of the second sub-pixels through the connecting line.

4. The array substrate according to claim 3, wherein a plurality of adjacent ones of the sub-pixels in each of the pixel rows form one of pixel groups, and the light-shielding layers corresponding to the sub-pixels in a same one of the pixel groups are electrically connected through the connecting line.

5. The array substrate according to claim 4, wherein each of the pixel rows comprises one or more of the pixel groups.

6. The array substrate according to claim 5, wherein each of the pixel rows comprises a plurality of the pixel groups, and each of the pixel groups comprises a same number of the sub-pixels.

7. The array substrate according to claim 5, wherein each of the pixel rows comprises a plurality of first pixel groups arranged in succession, and each of the first pixel groups comprises N number of adjacent ones of the sub-pixels, where N is a positive integer greater than or equal to 2.

8. The array substrate according to claim 7, wherein the first pixel groups located in adjacent ones of the pixel rows are dislocated from each other.

9. The array substrate according to claim 8, wherein N is an even number, and a dislocation distance is a distance between 1 to (N−1) number of the sub-pixels.

10. The array substrate according to claim 9, wherein a dislocation distance between the first pixel groups located in the adjacent ones of the pixel rows is a spacing of N/2 of adjacent ones of the sub-pixels.

11. The array substrate according to claim 10, wherein N=6, and each of the first pixel groups comprises at least one red sub-pixel, one blue sub-pixel, and one green sub-pixel.

12. The array substrate according to claim 7, wherein at least part of the pixel rows further comprises a second pixel group located at an edge of the pixel rows and adjacent to one of the first pixel groups, and each of the second pixel groups comprises M number of adjacent ones of the sub-pixels, where M is a positive integer greater than or equal to 1, M≠N, and M<2N.

13. The array substrate according to claim 1, wherein, in each of the sub-pixels, the one of the thin film transistors comprises an active layer, a gate, a source, and a drain that are stacked;
the active layer comprises a channel region, a lightly doped region, and a heavily doped region; and
an orthographic projection of one of the light-shielding layers on the active layer covers the channel region, the lightly doped region, and the heavily doped region.

14. The array substrate according to claim 13, wherein a distance between a boundary of an orthographic projection of one of the light-shielding layers on the base substrate and a boundary of an orthographic projection of the channel region adjacent to the one of the light-shielding layers on the base substrate is a, and a ≥2 microns.

15. The array substrate according to claim 13, wherein an orthographic projection of the connecting line on the base substrate and an orthographic projection of the gate on the base substrate do not overlap.

16. The array substrate according to claim 1, wherein a width of the connecting line ranges from 1 micron to 15 microns.

17. The array substrate according to claim 1, wherein a thickness of the light-shielding layer and a thickness of the connecting line both range from 300 Å to 1500 Å.

18. The array substrate according to claim 1, wherein a thickness of the connecting line and a thickness of the light-shielding layer are same.

19. A display panel, wherein the display panel comprises an array substrate and a second substrate disposed above thin film transistors of the array substrate, and a black matrix is disposed on a side of the second substrate close to the array substrate, wherein
the array substrate comprises:
a base substrate;
a plurality of data lines extending in a vertical direction, wherein the plurality of data lines comprise a plurality of first-type data lines and a plurality of second-type data lines arranged in parallel with the first-type data lines, and the first-type data lines and the second-type data lines are respectively configured with data voltages with opposite polarities;
a plurality of scan lines extending in a horizontal direction; and
a plurality of pixel units, wherein each of the pixel units comprises a plurality of sub-pixels defined by intersecting the scan lines and the data lines, and the plurality of sub-pixels comprise a plurality of first sub-pixels electrically connected to the first-type data lines and a plurality of second sub-pixels electrically connected to the second-type data lines,
wherein each of the sub-pixels is correspondingly provided with one of the thin film transistors and one of light-shielding layers located between the thin film transistor and the base substrate, and one of the light-shielding layers corresponding to each of the first sub-pixels is at least electrically connected to one of the light-shielding layers corresponding to one of the second sub-pixels through a connecting line; and
wherein an orthographic projection of the black matrix on the array substrate covers the connecting line.

20. A display device, wherein the display device comprises the display panel according to claim 19.
